(19) United States
(12) Patent Application Publication
(10) Pub. No.: US 2009/0236447 A1
(43) Pub. Date: Sep. 24, 2009

(54) METHOD AND APPARATUS FOR CONTROLLING GAS INJECTION IN PROCESS CHAMBER

(75) Inventors: THEODOROS PANAGOPOULOS, San Jose, CA (US); ALEXANDER PATERSON, San Jose, CA (US); JOHN P. HOLLAND, San Jose, CA (US); DAN KATZ, Saratoga, CA (US); EDWARD P. HAMMOND, IV, Hillsborough, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/053,105

(22) Filed: Mar. 21, 2008

(51) Int. Cl. B05B 1/14; H01L 21/306; C23C 16/00

(52) U.S. Cl. 239/548; 156/345.33; 118/715

(57) ABSTRACT

Methods and apparatus for processing substrates are provided herein. In some embodiments, a gas distribution apparatus may include a plurality of gas inlets configured to deliver a process gas to a process chamber; and a plurality of flow controllers having outlets coupled to the plurality of gas inlets for independently controlling the flow rate through each of the plurality of gas inlets. The gas distribution apparatus may be coupled to a process chamber for controlling the delivery of one or more process gases thereto.

### BACKGROUND

1. Field

Embodiments of the present invention generally relate to semiconductor processing, and more particularly, to methods and apparatus for controlling process gas injection in a process chamber.

2. Description of the Related Art

As the critical dimensions for semiconductor devices continue to shrink, there is an increased need for semiconductor process equipment that can uniformly process semiconductor substrates. One instance of where this need may arise is controlling the flow of process gases proximate the surface of a substrate disposed in a process chamber. The inventors have observed that, in conventional process chambers that utilize a single flow rate controller to controller the flow rate of all process gases entering the process chamber, process non-uniformities (for example, non-uniform deposition or etch rates) exist that are believed to be due, at least in part, to non-uniform flow of process gases entering the process chamber. Further, it has been observed that even within process chambers having uniform gas flows, processing conditions for various processes may still lead to non-uniformities developing on a substrate being processed.

Thus, there is a need in the art for an improved apparatus for processing substrates.

### SUMMARY

Methods and apparatus for processing substrates are provided herein. In some embodiments, a gas distribution apparatus may include a plurality of gas inlets configured to deliver a process gas to a process chamber; and a plurality of flow controllers having outlets coupled to the plurality of gas inlets for independently controlling the flow rate through each of the plurality of gas inlets. The gas distribution apparatus may be coupled to a process chamber for controlling the delivery of one or more process gases thereto.

In some embodiments, an apparatus for processing a substrate may include a process chamber having a substrate support contained therein; and a gas distribution system coupled to the process chamber, the gas distribution system may include a plurality of gas inlets configured to deliver a process gas to a process chamber; and a plurality of flow controllers having outlets coupled to the plurality of gas inlets for independently controlling the flow rate through each of the plurality of gas inlets. In some embodiments, the plurality of gas inlets may be disposed in a showerhead, in a wall of the process chamber, in a member proximate the substrate support, or combinations thereof.

In another aspect of the invention, methods for processing a substrate are provided. In some embodiments, a method for processing a substrate may include distributing a process gas or gas mixture to a process chamber via a plurality of gas inlets having independent control of the gas flow therethrough; and controlling a gas flow of the process gas or gas mixture through each gas inlet. In some embodiments, a flow rate at one or more gas inlets is different than a flow rate at one or more different gas inlets. In some embodiments, the composition of a process gas mixture provided to one or more of the plurality of inlets may be independently controlled. In some embodiments, the plurality of gas inlets may be grouped into at least two zones of gas inlets, each zone having at least one gas inlet. The gas flow of the process gas or gas mixture may be controlled differently in a first zone of the at least two zones than in a second zone of the at least two zones. In some embodiments, a gas flow may be provided through one or more of the plurality of gas inlets that has a gas flow direction that is different than at least one of the remaining ones of the plurality of gas inlets.

### BRIEF DESCRIPTION OF THE DRAWINGS

So that the manner in which the features of the present invention can be understood in detail, a more particular description of the invention may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-B depict schematic top views of gas distribution apparatus in accordance with some embodiments of the present invention.

FIG. 2 depicts a schematic side view of a gas distribution apparatus in accordance with some embodiments of the present invention.

FIGS. 3A-C depict illustrative zone configurations in a gas distribution apparatus in accordance with some embodiments of the present invention.

FIG. 4 depicts a partial schematic side view of a process chamber having a gas distribution apparatus in accordance with some embodiments of the present invention.

FIGS. 5A-B depict illustrative schematic top views of showerheads of a gas distribution apparatus showing example gas channel configurations in accordance with some embodiments of the present invention.

FIG. 6 depicts a schematic side view of a process chamber having a gas distribution apparatus in accordance with some embodiments of the present invention.

FIG. 7 depicts a partial schematic side view of a process chamber having a gas distribution apparatus in accordance with some embodiments of the present invention.

FIG. 8 depicts a flow chart of a process for controlling gas distribution to a process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods and apparatus for processing substrates having improved gas distribution control. In some embodiments, a process chamber may be provided having an improved gas distribution system for the injection of process gases into the process chamber. The improved gas distribution system facilitates providing a more controlled gas flow and/or more controlled distribution of process gases proximate the surface of a substrate disposed within the process chamber. Such controlled flow and distribution of process gases proximate the surface of the substrate may facilitate processing of the substrate as desired. In some embodiments, the controlled flow and distribution of process gases may be more uniform. In some embodiments, the controlled flow and distribution of process gases may be provided to facilitate more uniform processing of the substrate. It is contemplated that other, non-uniform processing profiles may also be obtained using the controlled flow and distribution of process gases provided by the inventive methods and apparatus of the present invention.

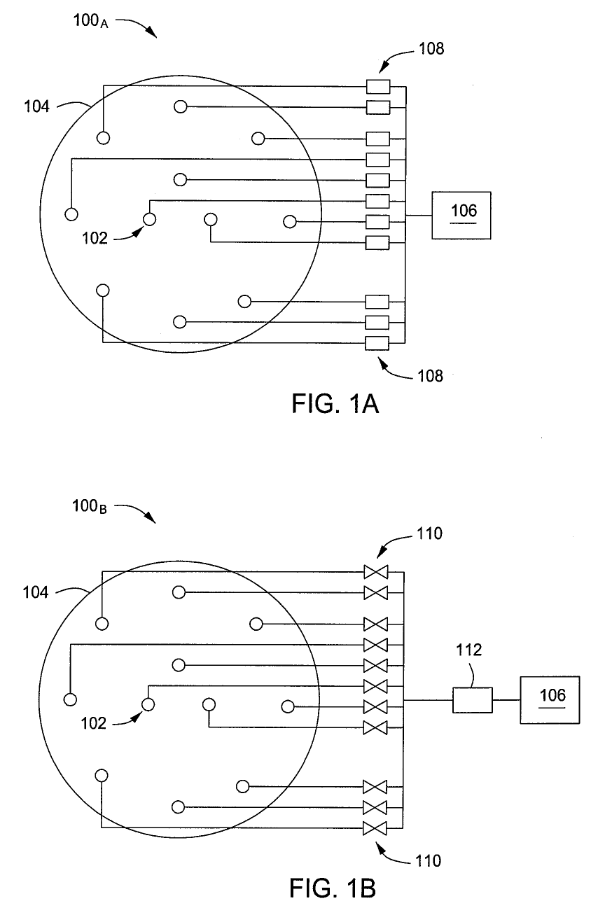

The inventive gas distribution apparatus provides independent control over the gas flow at each gas inlet coupling the gas distribution apparatus to a process chamber. The specific embodiments for providing such independent control may have a variety of forms. For example, as shown in FIG. 1A, a gas distribution apparatus 100A may be provided having a plurality of gas inlets 102 for providing a gas or gas mixture from one or more gas sources 106 to a process chamber (not shown). Each of the plurality of gas inlets 102 may be coupled to the gas source 106 via a flow controller 108, thereby facilitating independent control of the gas flow at each gas inlet 102. The plurality of flow controllers 108 may be at least one a mass flow controller, a flow ratio controller, or the like. In some embodiments, each of the plurality of first flow controllers 108 may comprise a mass flow controller.

In some embodiments, and as illustratively depicted in FIG. 1B, a gas distribution apparatus 100B may be provided having a plurality of gas inlets 102 for providing a gas or gas mixture from one or more gas sources 106 to a process chamber (not shown). Each of the plurality of gas inlets 102 may be coupled to the gas source 106 via one or more flow controllers 112 (one flow controller 112 shown in FIG. 1B). The flow controllers 112 may be similar to any of the flow controllers 108 discussed above with respect to FIG. 1A. The flow controllers 112 may be utilized for bulk metering of the process gas or gas mixture provided by the gas source 106 to the plurality of gas inlets 102.

To facilitate independent control of the gas flow at each gas inlet 102, a plurality of valves 110 may be coupled between the flow controllers 112 and the plurality of gas inlets 102. Each valve 110 may be independently controlled. The plurality of valves 110 may be at least one a continuously variable flow control valve, a multi-position flow control valve (such as, for example, a five position valve that may provide no flow, one-quarter flow, one-half flow, three-quarter flow, and full flow), a fast acting valve, or the like. In some embodiments, the plurality of valves 110 may be fast acting valves. Each fast acting valve may be cycled independently to control the quantity of gas delivered to each gas inlet 102. In some embodiments, the plurality of valves 110 may be multi-position flow control valves.

In some embodiments, and as illustratively depicted in FIGS. 1A-B, the plurality of gas inlets 102 may be disposed in a showerhead 104 or other gas distribution member coupled to the process chamber (not shown). In some embodiments, one or more gas inlets 102 may be provided in other locations, such as in a wall of a process chamber, in a member disposed proximate the substrate (such as a substrate support pedestal or an edge ring disposed on the substrate support pedestal and surrounding the substrate), or the like, as discussed in more detail below. The number of gas inlets 102 depicted FIGS. 1A-B are for illustrative purposes only and greater or fewer gas inlets may be utilized.

The gas source 106 may provide a single gas or a gaseous mixture. In some embodiments, multiple gas sources (not shown) may be coupled to one or more of the gas inlets 102 to provide single gases or gaseous mixtures from any single source or combination of sources. As such, one or more gaseous mixtures may be provided to one or more of the gas inlets 102 having varying compositions, in varying amounts, or the like.

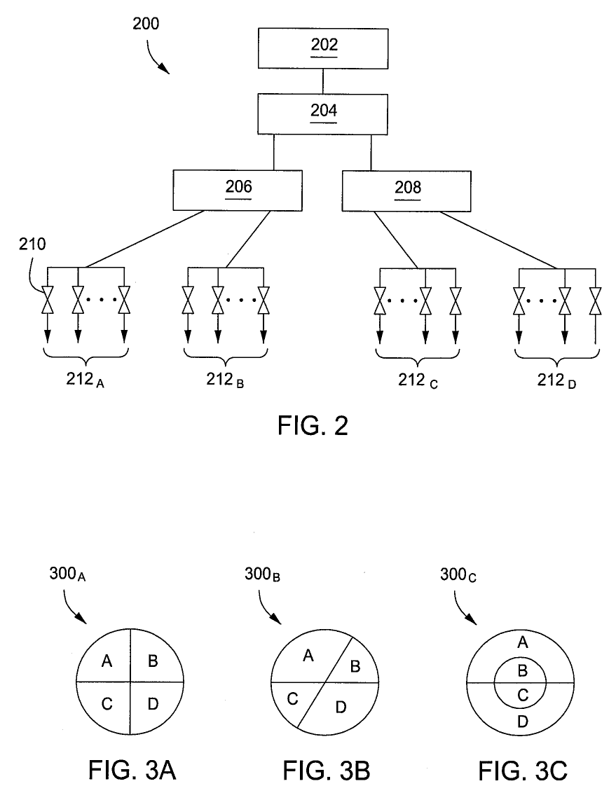

The embodiments shown in FIGS. 1A-B are illustrative, and additional embodiments are contemplated. For example, FIG. 2 shows a schematic side view of a gas distribution apparatus 200 in accordance with some embodiments of the present invention. The gas distribution apparatus 200 comprises a gas source 202 coupled to a plurality of gas inlets (not shown) via one or more stages of flow controllers. In the embodiment depicted in FIG. 2, the gas source 202 may be coupled to a flow ratio controller 204 at a first stage. The flow ratio controller 204 may have a single gas inlet coupled to the gas source 202 and at least two outlets. The flow ratio controller 204 may control the ratio of gas flowing through the outlets in any desirable amount. For example, in the example where there are just two outlets, the ratio may vary between 1:0 and 0:1.

Each outlet of the flow ratio controller 204 may further be coupled to a flow ratio controller, illustrated in FIG. 2 as two flow ratio controllers 206, 208 (e.g., providing a second stage of flow control). The flow ratio controllers 206, 208 may have single gas inlets coupled to the respective outlets of the flow ratio controller 204 and two or more outlets from which the relative flows of gases exiting therefrom may be controlled. Additional flow ratio controllers, or other flow controllers, may be coupled to the outlets of the flow ratio controllers 206, 208 in a continuing cascading pattern to provide additional stages of flow control and to provide a desired number of final outlets in the gas distribution apparatus 200, thereby providing increased flexibility in flow distribution and control.

The respective outlets of the flow ratio controllers 206, 208 (or whichever final stage of flow controllers are provided) may be coupled to one or more gas inlets (for example as described above with respect to FIGS. 1A-B) via a respective valve 210. The valves 210 may comprise any suitable flow control valve, as discussed above, and in some embodiments, comprise a multi-position valve (such as a five position valve). In some embodiments, each outlet of the final stage of flow controllers (e.g., flow ratio controllers 206, 208 in FIG. 2) may define a gas distribution zone (hereinafter, a zone) having one or more gas inlets contained therein, each gas inlet coupled to a respective valve 210. In the illustrative embodiment of FIG. 2, four zones 212_{A-D} are shown, each zone illustratively having a plurality of valves 210 coupled to a respective gas inlet (not shown) for providing a gas or gas mixture to a process chamber.

Thus, for example, as illustrated in FIG. 2, the gas source 202 may be coupled to a first stage flow controller (flow ratio controller 204) having two outputs, each of which may be coupled to a second stage of flow controllers (flow ratio controllers 206, 208). In some embodiments, common control over gas composition and/or flow characteristics may be utilized to define a plurality of zones (such as zones 212_{A-D}). Such zones are “virtual” in nature and may be defined by some common characteristic, such as gas flow rates, ratios, compositions, or the like, and are not physically separated within the gas distribution apparatus by barriers such as walls, baffles, or the like. The virtual zones may be created, removed, and/or altered at any time via control over the common characteristic as desired without any change in the hardware. For example, in some embodiments, the respective outputs of flow ratio controller 206 may be coupled to zones 212_{A} and 212_{B}, and the respective outputs of flow controller 208 may be coupled to zones 212_{C} and 212_{D}. Each zone 212_{A-D} may contain a plurality of gas inlets coupled to the respective outputs of the second stage flow controllers via a respective valve 210. FIG. 2 merely illustrates one embodiment for ease of understanding. It is further contemplated that the second stage flow controllers may number greater than two, that additional stages of flow control may be provided, and that greater or fewer numbers of zones may be provided.

The zones described above may be defined in any desired configuration or geometry to facilitate a desired gas distribution within a process chamber. The number of zones, their relative sizes, and/or their relative position may be configured (via flow control of one or more process gases) as desired for a particular process. For example, in some embodiments, uniform or non-uniform flow of process gases and/or process gas mixtures may be provided via a plurality of zones to a substrate being processed. Such zones may facilitate providing a desired flow of process gases and/or process gas mixtures to particular regions of a substrate being processed and may include one or more of varying flow rates, varying process gases, varying process gas mixtures, or the like. Moreover, as the zones may be created and/or altered by control over the gas or gases flowing through the plurality of gas inlets (not shown)—as compared to zones created by baffles or other physical barriers within, for example, a showerhead—zones may be advantageously created, removed, and/or altered as needed, such as for example, for a particular process, between process steps, during one or more process steps, or the like, without changing the hardware of the gas distribution apparatus.

FIGS. 3A-C depict illustrative zone configurations in a gas distribution apparatus in accordance with some embodiments of the present invention. The schematic representations of FIGS. 3A-C may correspond to a substrate disposed in the process chamber, to an inner volume of the process chamber, or the like. In some embodiments, as shown in FIG. 3A, a gas distribution apparatus 300_{A} may be provided having a plurality of zones defined by one or more lines extending from an inner location of the gas distribution apparatus 300_{A}. For example, FIG. 3A depicts four zones (labeled A-D), each covering a quarter of the gas distribution apparatus 300_{A} defined by four lines extending from a center point of the gas distribution apparatus 300_{A}. In some embodiments, as shown in FIG. 3A, the size of each zone within the gas distribution apparatus may be substantially equal.

In some embodiments, the size of some zones within the gas distribution apparatus may be different (e.g., the zones may be distributed unequally and/or may cover different sized areas of the gas distribution apparatus). For example, as shown in FIG. 3B, a gas distribution apparatus 300_{B} may be provided having a plurality of zones defined by one or more lines extending from an inner location of the gas distribution apparatus 300_{B}, wherein the lines define unequal portions within the gas distribution apparatus 300_{B}. For example, FIG. 3B depicts four zones (labeled A-D) defined by four lines extending from a center point of the gas distribution apparatus 300_{A} that are not azimuthally equidistantly arranged about the center point. As illustratively shown in FIG. 3B, zones A and D cover larger portions of the gas distribution apparatus 300_{B} and zones B and C cover smaller portions of the gas distribution apparatus 300_{B}.

In some embodiments, the zones may be configured to cover inner and outer portions of the gas distribution apparatus. The zones may cover one or more inner regions of the gas distribution apparatus and one or more outer regions of the gas distribution apparatus. For example, FIG. 3C, depicts a gas distribution apparatus 300_{C} having a plurality of inner zones B and C and a plurality of outer zones A and D. The inner zones B and C may together define an inner portion of the gas distribution apparatus 300_{C} (for example, corresponding to an inner portion of a substrate disposed beneath the gas distribution apparatus). The outer zones A and D may together define an outer portion of the gas distribution apparatus 300_{C} (for example, corresponding to an outer portion of a substrate disposed beneath the gas distribution apparatus).

The zone configurations of FIGS. 3A-C are merely illustrative, and it is contemplated that gas distribution apparatus in accordance with embodiments of the present invention may utilize any zone configuration capable of facilitating uniform or non-uniform flow of process gases and/or process gas mixtures to a substrate being processed within a process chamber, and/or targeted flow of process gases and/or process gas mixtures to particular regions of a substrate being processed. For example, the zones do not need to be symmetrically arranged about a center point of the gas distribution apparatus and may be offset (for example, to compensate for process conditions within the process chamber, such as plasma effects, magnetic field effects, flow patterns due to locations of the gas inlets, pumping effects, or the like). As discussed above, the number of zones may vary, the relative sizes may vary, the geometry and location of the zones may vary, and the like. As also discussed above, the number, relative sizes, geometry, location, and the like of the zones may be created, removed, and/or altered at any time via control of the gas flows through the plurality of inlets of the gas distribution apparatus.

Although FIGS. 3A-C shows top views of gas distribution apparatus having a circular cross-section, it is contemplated that the gas distribution apparatus may have other cross-sections and/or may additionally utilize gas inlets located at other locations (such as in other locations of the process chamber or proximate the substrate support pedestal) which may be disposed within additional zones not shown in FIGS. 3A-C.

As independent control of the flow and/or mixture of process gases provided at each gas inlet is provided in the inventive gas distribution apparatus disclosed herein, the number of zones or their configuration may be created and or altered within a process step or between process steps via control of the relative flow and or gas mixture provided at each gas inlet. Thus, in any of the embodiments discussed herein, the existence of zones, the number of zones, the configuration of zones, and the like, may be controlled as needed or desired for a particular application or process.

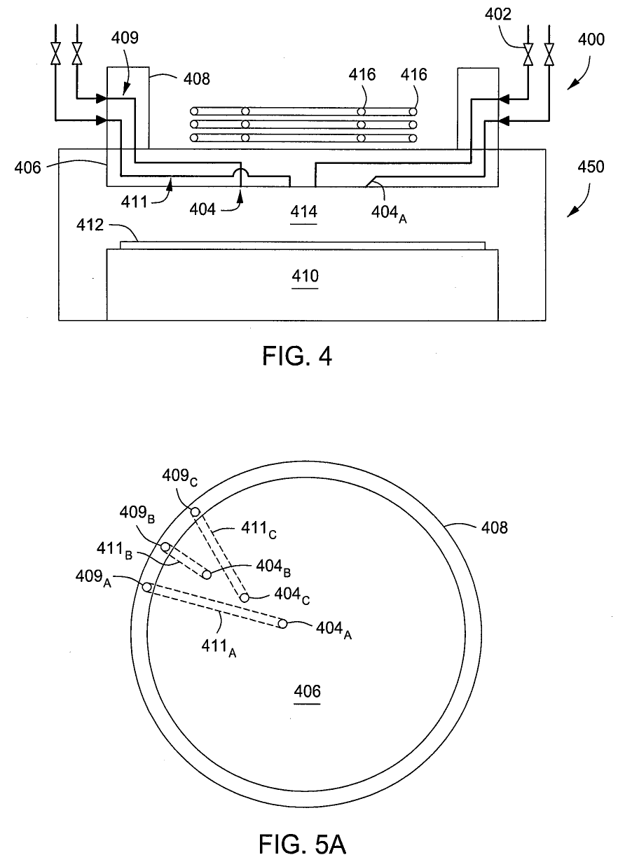

FIG. 4 illustrates a partial schematic side view of a gas distribution apparatus 400 coupled to a process chamber 450 in accordance with some embodiments of the present invention. The gas distribution apparatus 400 may be configured in accordance with any of the gas distribution apparatus described above, and for clarity and ease of understanding, is only partially displayed in FIG. 4. In some embodiments, the gas distribution apparatus 400 may couple a plurality of gas inlets 404 to one or more gas sources (not shown) via at least a plurality of flow controllers (such as valves 402 depicted in FIG. 4).

In some embodiments, the gas distribution apparatus 400 may include a showerhead 406 and a gas distribution ring 408 coupled thereto. The showerhead 406 may have the plurality of gas inlets 404 disposed therein. Each gas inlet 404 in the showerhead 406 has an individual gas flow channel 411 provided to maintain independent control over the gas flow and distribution amongst the plurality of gas inlets 404. The gas distribution ring 408 contains corresponding gas flow channels 409, each configured to join with respective ones of the gas flow channels 411 in the showerhead 406. The gas inlets 404, gas flow channels 409, and gas flow channels 411 may be formed by any suitable methods, such as by drilling one or more holes in the gas distribution ring 408 and the showerhead 406. In some embodiments, an o-ring or other sealing mechanism (not-shown) may be provided between the showerhead 406 and the gas distribution ring 408 at each gas flow channel 409, 411 to facilitate reducing or eliminating any leakage of the process gases. The gas distribution ring 408 may be coupled to each of the flow controllers (e.g., valves 402) via respective gas flow channels 409.

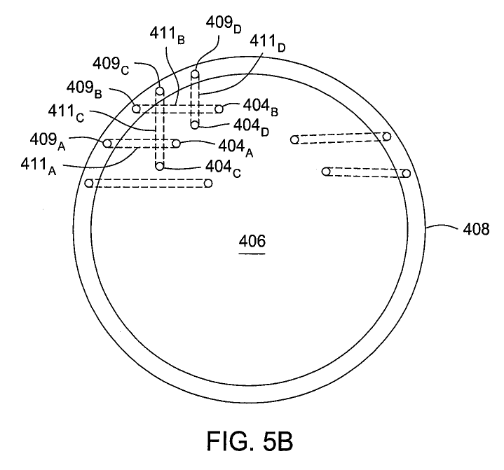

The respective gas flow channels 409, 411 disposed in the gas distribution ring 408 and the showerhead 406 may be configured in various ways to facilitate the independent distribution of the gas flow amongst the plurality of gas inlets 404. For example, as shown in FIG. 5A, in some embodiments, the plurality of gas inlets 404 (depicted as gas inlets 404_{A-C}) and the flow channels formed in the gas distribution ring 408 (depicted as flow channels 409_{A-C}) may be coupled by forming respective flow channels in the showerhead 406 (depicted as flow channels 411_{A-C}) that do not overlap. Such flow channels may be formed in the showerhead 406 in a single level (e.g., on a common plane) without interference between the individual flow channels.

In some embodiments, at least some of the flow channels 409 may overlap (for example, due to space limitations, number and location of the plurality of gas inlets, or the like). In some embodiments, as shown in FIG. 5B, at least some of the plurality of gas inlets 404 (depicted as gas inlets 404_{A-D}) and the corresponding flow channels formed in the gas distribution ring 408 (depicted as flow channels 409_{A-D}) may be coupled by forming respective flow channels in the showerhead 406 (depicted as flow channels 411_{A-D}) that overlap. Such overlapping flow channels may be formed in the showerhead 406 on multiple levels (e.g., on different planes) to facilitate maintaining independence between the individual flow channels. For example, the schematic side view of FIG. 4 depicts flow channels 411 that are formed on different planes within the showerhead 406. Although described as being formed on different levels, or planes, the flow channels 411 may also suitably be formed at different angles that prevent nearby flow channels 411 from intersecting with each other. It is contemplated that variables such as one or more of the thickness of the showerhead, the number of gas inlets, the locations of the gas inlets, and the like, will determine the ultimate configuration of the flow channels in the showerhead. Similar considerations may be applied to the formation and location of gas flow channels 409 formed in the gas distribution ring 408. For example, the height and/or thickness of the gas distribution ring 408 may be varied as needed to fit the desired number and location of gas flow channels 409 to mate with the gas flow channels 411 of the showerhead 406.

Returning to FIG. 4, in addition to providing independent flow control and distribution of gases within the process chamber 450 by utilizing flow controllers, the gas distribution apparatus of the present invention may further control the distribution of process gases within the process chamber 450 via control of the directional flow of the gas at desired locations. For example, as illustrated in FIG. 4, the gas inlets 404 of the gas distribution apparatus 400 may be configured to provide process gas flow in a desired direction relative to a substrate 412 being processed. For example, typically, gas may be introduced into a process chamber perpendicular to a substrate from a showerhead, or parallel to the substrate from a side nozzle in a process chamber. In some embodiments, one or more of the gas inlets 404 (such as gas inlet 404_{A} shown in FIG. 4) may be oriented at a non-perpendicular angle to the substrate 412 to facilitate the flow of process gases in a non-normal direction relative to the substrate surface. The gas distribution apparatus may be configured such that the plurality of gas inlets may be oriented perpendicular, non-perpendicular, or combinations thereof with respect to the substrate surface.

The showerhead 406 may be disposed in an upper region of the process chamber 450, generally opposed to a substrate support 41 0 for supporting thereon a substrate 412 to be processed and bounding a processing volume 414 defined by the substrate support 410 and the showerhead 406. The gas distribution ring 408 may be coupled to an upper surface of the showerhead 406 proximate an outer perimeter thereof. The gas distribution ring 408 may be configured to minimize the physical space occupied by the apparatus and/or to facilitate assembly and/or use with other components of the process chamber 450. For example, in some embodiments, an RF source (not shown) may be coupled to the processing chamber 450 for plasma processing of the substrate 412. In some embodiments, and as shown in FIG. 4, the process chamber 450 may utilize RF power that is inductively coupled to the processing chamber 450 via an antenna comprising at least one inductive coil element (two inductive coil elements 416 shown in FIG. 4). In such embodiments, the ceiling of the process chamber 450 and the showerhead 406 may be fabricated from a dielectric material. Alternatively, the process chamber 450 may utilize RF power that is capacitively coupled to the processing chamber 450 directly via an upper electrode disposed proximate an upper portion of the process chamber 450. In some embodiments, the upper electrode may be a conductor formed, at least in part, by one or more of the ceiling of the process chamber 450, the showerhead 406, or the like. In embodiments where RF power is coupled to the showerhead 406, the showerhead 406 may be fabricated from a conductive material.

In operation, process gases may flow from the plurality of gas inlets 404 disposed in the showerhead 406 into the processing volume 414 to process the substrate 412. The gas distribution apparatus 400 facilitates control over the gas flow, composition, direction, and distribution into the process chamber 450 from each gas inlet 404. Such processing may include any processing wherein one or more gases may be provided to process a substrate, such as for treating a surface of the substrate, etching the substrate, depositing materials on the substrate, or the like.

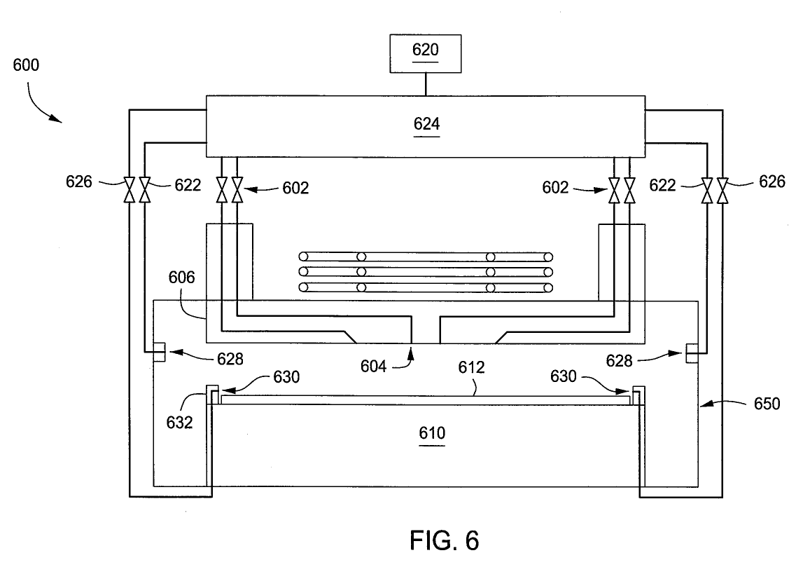

FIG. 6 depicts a schematic side view of a process chamber 650 having a gas distribution apparatus 600 in accordance with some embodiments of the present invention. The gas distribution apparatus 600 may be configured in accordance with any of the gas distribution apparatus described above. The gas distribution apparatus 600 may be coupled to the process chamber 650 for delivering process gases, mixtures of process gases, or the like, to a substrate 612 contained therein on a substrate support pedestal 610. The process chamber 650 may be any suitable process chamber for processing a substrate using the gas distribution apparatus to provide a gas flow that may be uniform or non-uniform and/or that may have controlled flow ratios, directions, and/or distributions of process gases within the process chamber 650.

In some embodiments, the gas distribution apparatus 600 may couple a plurality of gas inlets 604 to one or more gas sources (one gas source 620 shown) via one or more flow controllers (such as flow controller 624) and a plurality of valves (such as valves 602). The plurality of gas inlets 604 may be disposed in a showerhead 606 disposed in an upper portion of the process chamber 650. Alternatively or in combination, the gas distribution apparatus 600 may couple a plurality of gas inlets 628 to the one or more gas sources via the flow controller and a plurality of valves (such as valves 622). The gas inlets 628 may be disposed on a sidewall or other location in the process chamber 650 separate from the showerhead 606. Alternatively or in combination, the gas distribution apparatus 600 may couple a plurality of gas inlets 630 to the one or more gas sources via the flow controller and a plurality of valves (such as valves 626). The gas inlets 630 may be disposed in or proximate the substrate support pedestal 610. In the embodiment depicted in FIG. 6, the gas inlets 630 may be disposed in an edge ring 632 disposed on the substrate support pedestal 610 and surrounding the substrate 612.

The flow controller 624 may have a plurality of outlets for independently coupling to each of the plurality of gas inlets (e.g., 604, 628, 630). Alternatively, at least some of the outlets of the flow controller 624 may be grouped together to provide an output to a grouping of inlets. For example, one outlet may be coupled to the plurality of gas inlets 604 in the showerhead 606, or a plurality of outlets may be coupled to subsets of the inlets 604 (such as inlets grouped in inner and outer zones, or other zone configurations, as discussed above), one outlet may be coupled to the plurality of gas inlets 628 disposed on the sidewall or other location in the process chamber 650, and/or one inlet may be coupled to the plurality of gas inlets 630 disposed in or proximate the substrate support pedestal 610. In addition, although one flow controller 624 and one gas source 620 is illustratively shown in FIG. 6, multiple flow controllers and/or multiple gas sources may be provided in order to provide desired control over gas flow, flow rates, flow ratios, gas compositions, gas distribution, and the like, or combinations thereof.

As discussed above with respect to FIG. 4, in addition to providing independent flow control and distribution of gases within the process chamber 650 by utilizing flow controllers, the gas distribution apparatus 600 may further control the distribution of process gases within the process chamber 650 via control of the directional flow of the gas at desired locations. For example, as illustrated in FIG. 6, the gas inlets 604 of the gas distribution apparatus 600 may be configured to provide process gas flow in a desired direction relative to a substrate 612 being processed. In some embodiments, one or more of the gas inlets 604 may be oriented at a non-perpendicular angle to the substrate 612 to facilitate the flow of process gases in a non-normal direction relative to the substrate surface. In the embodiment depicted in FIG. 6, the outer gas inlets 604 are shown angled inwards, to direct the gas flow radially inwards. It is contemplated that other configurations providing a desired gas flow in other directions, and/or from other locations may be utilized. For example, in addition to different combinations of angles of gas inlets 604 on the showerhead 606, one or more of the gas inlets 628 or the gas inlets 630 may be angled as desired to provide a directional gas flow as desired with respect to the substrate 612.

In operation, process gases from the one or more gas sources (e.g., 620) may be metered by the flow controllers (e.g., 624) and provided to the plurality of gas inlets (e.g., 604, 628, 630) via the plurality of valves (e.g., 602, 622, 626) to independently control the flow, composition, direction, and/or distribution of the process gas(es) into the process chamber 650 to process the substrate 612. Such processing may include any processing wherein one or more gases may be provided to process a substrate, such as for treating a surface of the substrate, etching the substrate, depositing materials on the substrate, or the like.

In some embodiments, the orientation of each gas inlet (404, 704, 706) may be set by an actuator mechanism (not shown) to any desired orientation (e.g., parallel to, perpendicular to, or angled with respect to the substrate surface).. The orientation of one or more gas inlets may be held fixed during the processing of a substrate or may be varied during the processing of the substrate. Alternatively or in combination, a number of gas inlets may be disposed near to each other and angled in varying directions. The desired angle for the distribution of the process gases may then be controlled by selectively choosing which of the gas inlets to utilize during a particular process or over the course of a particular process.

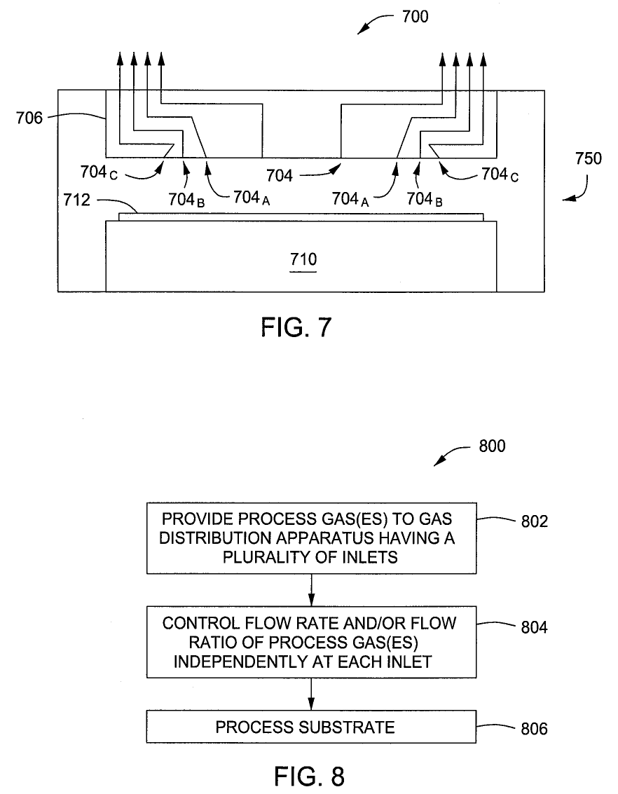

For example, FIG. 7 depicts a partial schematic view of a gas distribution apparatus 700 coupled to a process chamber 750. The gas distribution apparatus 700 and the process chamber 750 may be similar to, or may incorporate any combination of the features of, the gas distribution apparatus and process chambers discussed above to the extent not inconsistent with the following discussion. In some embodiments, gas distribution apparatus 700 may include a plurality of gas inlets 704 disposed in a showerhead 706. At least some of the plurality of gas inlets 704 may be disposed at varying angles with respect to a substrate support pedestal 710 for supporting a substrate 712 thereon. For example, as illustratively depicted in FIG. 7, some of the gas inlets may be angled radially outwards (e.g., 704_{C}), some of the gas inlets may be perpendicular to the substrate support pedestal 710 (e.g., 704_{B}), and some of the gas inlets may be angled radially inwards (e.g., 704_{A}). In operation, one or more of the gas inlets 704_{A-C} may be selectively or predominantly used to control the direction and or composition of gas flowing proximate desired regions of the substrate 712.

The gas distribution apparatus discussed above may be utilized to control the gas flow, composition, direction, and/or distribution during processing or for varying processes in a variety of ways. For example, FIG. 8 depicts a flow chart of a process 800 for controlling gas distribution to a process chamber in accordance with some embodiments of the present invention. The process 800 may begin at 802 where one or more process gas(es) may be provided to a gas distribution apparatus having a plurality of gas inlets. The gas distribution apparatus may be any of the gas distribution apparatus as discussed herein.

Next, at 804, the flow rate and/or flow ratio of the one or more process gas(es) may be controlled independently at each gas inlet. Such control may include control over one or more of the gas flow, composition, direction, and/or distribution and may be utilized to create, remove, and/or alter a plurality of zones having at least one gas inlet. Next, at 806, a substrate may be processed using the one or more process gases delivered to the process chamber via the gas distribution apparatus. The processing at 806 and/or the control at 804 may vary over the course of a process, across individual steps of a multi-step process, or between different processes (e.g., 802 and 804 may be repeated within a process, between process steps, and/or between processes). The control may be implemented manually or may be selected based upon a process recipe.

Thus, methods and apparatus for processing substrates have been provided herein that provide improved control over gas flow, flow rates, flow ratios, gas compositions, gas flow direction, gas distribution, and the like, or combinations thereof. The improved control of gas distribution facilitates improvement of substrate processing, such as etching, deposition, treating, or otherwise processing the substrate as desired. The process gas(es) provided to the substrate may be substantially uniform, non-uniform, and/or targeted to specific regions of the substrate surface.

While the foregoing is directed to embodiments of the present invention, other and further embodiments of the invention may be devised without departing from the basic scope thereof, and the scope thereof is determined by the claims that follow.

What is claimed is:

1. A gas distribution apparatus, comprising:
a plurality of gas inlets configured to deliver a process gas to a process chamber; and
a plurality of flow controllers having outlets coupled to the plurality of gas inlets for independently controlling the flow rate through each of the plurality of gas inlets.

2. The apparatus of claim 1, wherein each flow controller comprises a continuously variable flow rate valve, a multi-position variable flow rate valve, a fast acting valve, a mass flow controller, or a flow ratio controller.

3. The apparatus of claim 1, further comprising:
a mass flow controller having an outlet coupled to inlets of the plurality of flow controllers, wherein the flow controllers comprise at least one of a continuously variable flow rate valve, a multi-position variable flow rate valve, or a fast acting valve.

4. The apparatus of 1, further comprising:
a first flow ratio controller having a pair of outlets coupled to respective inlets of a pair of second flow ratio controllers, the second flow ratio controllers having outlets coupled to inlets of the plurality of flow controllers.

5. The apparatus of claim 4, wherein the plurality of flow controllers comprise at least one of a continuously variable flow rate valve, a multi-position variable flow rate valve, or a fast acting valve.

6. The apparatus of claim 5, wherein the plurality of flow controllers comprise a multi-position variable flow rate valve.

7. The apparatus of claim 1, wherein at least one gas inlet is oriented at a different angle than at least one other gas inlet.

8. An apparatus for processing a substrate, comprising:
a process chamber having a substrate support contained therein; and
a gas distribution system coupled to the process chamber, the gas distribution system comprising:
a plurality of gas inlets configured to deliver a process gas to a process chamber; and
a plurality of flow controllers having outlets coupled to the plurality of gas inlets for independently controlling the flow rate through each of the plurality of gas inlets.

9. The apparatus of claim 8, wherein the plurality of gas inlets are disposed in a showerhead, in a wall of the process chamber, in a member proximate the substrate support, or combinations thereof.

10. The apparatus of claim 8, further comprising:
a mass flow controller having an outlet coupled to inlets of the plurality of flow controllers, wherein the flow controllers comprise at least one of a continuously variable flow rate valve, a multi-position variable flow rate valve, or a fast acting valve.

11. The apparatus of 8, further comprising:
a first flow ratio controller having a pair of outlets coupled to respective inlets of a pair of second flow ratio controllers, the second flow ratio controllers having outlets coupled to inlets of the plurality of flow controllers.

12. The apparatus of claim 11, wherein the plurality of flow controllers comprise at least one of a continuously variable flow rate valve, a multi-position variable flow rate valve, or a fast acting valve.

13. The apparatus of claim 8, wherein at least one gas inlet is oriented at a different angle than at least one other gas inlet.

14. The apparatus of claim 8, further comprising:
one or more gas sources coupled to the plurality of gas inlets via the plurality of flow controllers.

15. The apparatus of claim 8, further comprising:
a plurality of gas sources coupled to the plurality of gas inlets via the plurality of flow controllers, wherein a process gas mixture provided to the process chamber by the plurality of gas sources may have a varying composition at each of the plurality of gas inlets via control by the gas distribution system.

16. A method for processing a substrate, comprising:
distributing a process gas or gas mixture to a process chamber via a plurality of gas inlets having independent control of the gas flow therethrough; and
controlling a gas flow of the process gas or gas mixture through each gas inlet.

17. The method of claim 16, wherein a flow rate at one or more gas inlets is different than a flow rate at one or more different gas inlets.

18. The method of claim 16, wherein the process gas comprises a process gas mixture, and further comprising:
controlling the composition of the process gas mixture provided to one or more of the plurality of inlets.

19. The method of claim 18, wherein a flow rate of process gases comprising the process gas mixture is different at at least one gas inlet.

20. The method of claim 16, wherein controlling the gas flow further comprises:
grouping the plurality of gas inlets into at least two zones of gas inlets, each zone having at least one gas inlet; and
controlling the gas flow of the process gas or gas mixture differently in a first zone of the at least two zones than in a second zone of the at least two zones.

21. The method of claim 16, further comprising:
providing a gas flow through one or more of the plurality of gas inlets that have a gas flow direction that is different than at least one of the remaining ones of the plurality of gas inlets.
